(19) United States
(12) Patent Application Publication
(10) Pub. No.: US 2022/0190641 A1
(43) Pub. Date: Jun. 16, 2022

(54) ADAPTIVE METERING IN A SMART GRID

(71) Applicant: Landis+Gyr Innovations, Inc., Alpharetta, GA (US)

(72) Inventors: David Decker, Atlanta, GA (US); Matt Karlgaard, Brainerd, MN (US); Ruben E. Salazar Cardozo, Johns Creek, GA (US); Keith Mario Torpy, Sydney (AU); James Randall Turner, Alpharetta, GA (US)

(21) Appl. No.: 17/122,453

(22) Filed: Dec. 15, 2020

(51) Int. Cl. H02J 13/00; G01R 22/06

(52) U.S. Cl. CPC H02J 13/00026; H02J 13/00034; G01R 22/061

(57) ABSTRACT

An implementation of a utility meter is connected to a resource and to a customer premises. The utility meter includes a sensor, a converter, and a radio. The sensor is configured to detect a characteristic of resource usage by the customer premises. The converter is configured to convert the characteristic to raw consumption data describing the resource usage. The radio is configured to transmit the raw consumption data output by the converter to a remote processing system. The remote processing system includes one or both of a fog and a cloud. The fog is associated with a geographic region of the utility meter and performs data processing on the raw consumption data and on regional raw consumption data received from other endpoints in the geographic region. The cloud performs data processing on the raw consumption data as well as on data received from other endpoints across various geographic regions.

### TECHNICAL FIELD

Some implementations described herein relate to utility meters and, more specifically, to adaptive metering whereby a utility meter is implemented as a connected sensor in an adaptive smart grid environment.

### BACKGROUND

A smart grid is an electrical grid utilizing some aspects of intelligence. For instance, a smart grid includes a set of utility meters, or smart meters, where each utility meter is configured to provide data needed for grid intelligence. In a smart grid, a utility meter may implement advanced meter reading (AMR). A utility meter with AMR regularly transmits its consumption data to a central processing system, also referred to as a headend system. Specifically, after the conclusion of each interval, the utility meter transmits to the headend system a data packet including the corresponding consumption data, which describes the resource consumption in that interval. Additionally, the utility meter periodically sends to the headend system meter snapshots describing the state of the meter. The headend system can utilize the consumption data and meter snapshots to generate bills and to analyze connectivity or other aspects of the smart grid. The transmission of data through the smart grid can occur via a radio frequency (RF) mesh, RF point-to-multipoint technology, or by power line technology from the utility meter to the headend system.

### SUMMARY

In one implementation, a utility meter is connected to a power grid and to a customer premises. The utility meter includes a sensor, an analog-to-digital (A/D) converter, and a radio. The sensor is configured to detect an electrical characteristic of electricity usage of the power grid by the customer premises. The A/D converter is configured to convert the electrical characteristic to raw consumption data describing the electricity usage by the customer premises. The radio is configured to transmit the raw consumption data output by the A/D converter to a remote processing system. The remote processing system includes a fog processing system having one or more fog devices. The fog processing system is associated with a geographic region of the utility meter, and the fog processing system is configured to perform data processing on the raw consumption data and on regional raw consumption data received from other endpoints inside the geographic region.

In another implementation, a system includes a utility meter and a remote processing system. The utility meter is connected to a resource and to a customer premises. The utility meter includes a sensor, a converter, and a radio. The sensor is configured to detect a characteristic of usage of the resource by the customer premises. The converter is configured to convert the characteristic to raw consumption data describing the usage by the customer premises. The radio is configured to transmit the raw consumption data. The remote processing system includes a fog processing system and a cloud processing system and is configured to receive the raw consumption data from the utility meter. The fog processing system includes one or more fog devices associated with a geographic region of the utility meter, and the fog processing system is configured to perform data processing on the raw consumption data and on regional raw consumption data received from other endpoints inside the geographic region. The cloud processing system includes one or more cloud devices. The cloud processing system is configured to perform centralized data processing on the raw consumption data and on various raw consumption data from the other endpoints inside the geographic region as well as from additional endpoints outside the geographic region.

In yet another implementation, a method performed by a utility meter includes connecting to a power grid and to a customer premises. According to the method, the utility meter utilizes a sensor to determine an electrical characteristic indicating electricity usage of the power grid by the customer premises. The utility meter converts the electrical characteristic to raw consumption data describing the electricity usage by the customer premises. The utility meter transmits the raw consumption data describing the electricity usage to a fog processing system for data processing of regional consumption data received from a first set of endpoints inside a geographic region associated with the fog processing system. The utility meter also transmits, potentially by way of the fog processing system, the consumption data describing the electricity usage to a cloud processing system for centralized data processing of various consumption data received from the first set of endpoints inside the geographic region and from a second set of endpoints outside the geographic region.

These illustrative aspects and features are mentioned not to limit or define the presently described subject matter, but to provide examples to aid understanding of the concepts described in this application. Other aspects, advantages, and features of the presently described subject matter will become apparent after review of the entire application.

### BRIEF DESCRIPTION OF THE FIGURES

These and other features, aspects, and advantages of the present disclosure are better understood when the following Detailed Description is read with reference to the accompanying drawings.

FIG. 1 is a diagram of an example of a smart grid, according to some implementations described herein.

FIG. 2 is a diagram of another example of a smart grid, according to some implementations described herein.

FIG. 3 is a diagram of yet another example of a smart grid, according to some implementations described herein.

FIG. 4 is a flow diagram of a method of processing data through the smart grid, according to some implementations described herein.

FIG. 5 is a diagram of a utility meter in the smart grid, according to some implementations described herein.

### DETAILED DESCRIPTION

A utility service provider can have numerous utility meters, also referred to as meters, corresponding to its numerous customers. Each utility meter represents an expense for that utility service provider. Further, when utility service providers seek to integrate increased intelligence into utility meters to enable more intelligent features within a smart grid, the cost of a meter increases. In total, the cost of the meters under the control of the utility service provider can represent a significant expense, such that a reduction in the cost of a meter would lead to a significant savings across the various meters.

With recent increases in computing capabilities and with the increase in communications bandwidth availability, however, it is now possible to shift the locations in which intelligence is implemented in a smart grid. Specifically, intelligence can be shifted from the utility meters and from the headend system. Some implementations described herein can reduce the cost of a meter by moving processing conventionally performed on the meter to a fog processing system, also referred to as a fog, or to a cloud processing system, also referred to as a cloud.

In some implementations, the meter itself may include a reduced amount of hardware or software (e.g., firmware) and may perform a reduced amount of processing as compared to a conventional meter. For example, a utility meter described herein, also referred to as an adaptive meter, may be an Internet-of-Things (IoT) sensor configured to sense a characteristic (e.g., current or voltage) of resource consumption and to publish, to a remote processing system, raw consumption data based on that characteristic. The raw consumption data may be, for instance, a digital representation of the characteristic resulting from an analog-to-digital (A/D) conversion. The remote processing system may include a cloud processing system and one or more fog processing systems. In some implementations, a fog processing system is associated with a geographic region and may provide regional processing, which may be performed in real time or near-real time, on raw consumption data provided by meters in that geographic region. In contrast, the cloud processing system may provide more centralized processing outside a headend system for meters across various geographic regions. In such implementations, intelligence in a smart grid is shifted from the meter itself to the fog processing system or to the cloud processing system. Additionally, intelligence can be shifted from the headend system as well, thus reducing the load on the headend system and enabling the headend system to specialize in certain meter-related tasks rather than performing the bulk of meter-related tasks.

Some implementations herein provide an adaptive and intelligent IoT metering solution architecture based on low-complexity, low-cost endpoint hardware (e.g., a utility meter) coupled with advanced communications. For instance, an example of a utility meter is a simplified, low-cost, wireless-connected IoT smart sensor. Additionally, some implementations involve a suite of fog-based services or cloud-based service that can perform a significant portion of the information processing needed to support system and service operations. The fog- and cloud-based services can be implemented through a variety of technologies such as data processing, analytics, or machine learning or other artificial intelligence. By reducing the complexity and the cost of utility meters, the overall cost of the smart grid can be reduced while also providing significant advantages through the placement of services in the fog and in the cloud. Advantages of some implementations include increased modularity of software services, potential optimization in overall communications bandwidth used, simplification of the software update process, and increased flexibility in system configuration, operation, and management for utility meters. The optimization of communications bandwidth can be particularly useful when the smart grid utilizes a lossy network, such as a radio frequency (RF) mesh. Further, as described herein, some implementations provide improvements over an existing smart grid in terms of flexibility, scalability, or adaptability.

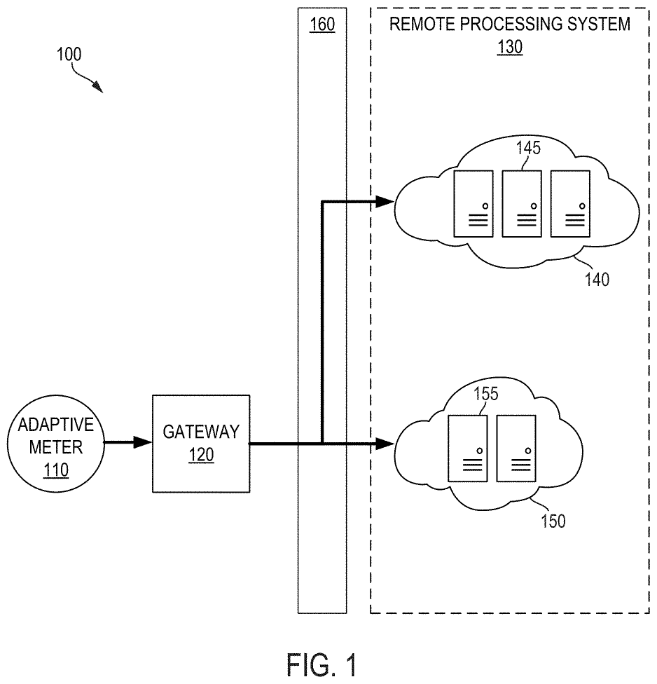

FIG. 1 is a diagram of an example of a smart grid system 100, also referred to herein as a smart grid 100, according to some implementations described herein. In some implementations, the smart grid 100 is an electrical grid supported by intelligence implemented through various devices. The smart grid 100 may include one or more adaptive meters 110 and a remote processing system 130. An adaptive meter 110 is a utility meter as described herein. As shown in FIG. 1, the remote processing system 130 may include one or both of a cloud processing system 140, also referred to as a cloud, and a fog processing system 150, also referred to as a fog.

Throughout this disclosure, references are made to adaptive meters 110 being electric meters; however, an adaptive meter 110 may alternatively be a gas meter, a water meter, or some other type of meter. In an implementation where the adaptive meters 110 are not electric meters, it will be understood that the smart grid is replaced by another type of network that connects the adaptive meters 110, the remote processing system 130, and other devices as described herein.

In some implementations, an adaptive meter 110 is configured to determine and to transmit data, which may include raw data such as raw consumption data. To this end, the adaptive meter 110 may include a sensor, a converter, a microprocessing unit (MCU) or other processing unit, and a radio. The MCU or other processing unit may include memory as needed to perform the tasks described herein or other tasks of the adaptive meter 110, or the adaptive meter 110 may include a separate memory device. The sensor may detect a characteristic of resource consumption by a customer premises (i.e., occurring on a customer premises) associated with the adaptive meter 110. For instance, if the adaptive meter 110 is an electric meter, the sensor of the adaptive meter 110 may detect an electrical characteristic such as voltage or current as an indication of electricity consumption. The converter may be an A/D converter and may convert the detected characteristic into raw sensed data, which may be numerical values or other digital data describing the resource consumption. The raw sensed data may be used as consumption data, or the microprocessor may provide further processing, such as transforming the raw sensed data into an appropriate format for transmission, to produce raw consumption data. Depending on the type of adaptive meter 110 (e.g., electric, water, gas), the raw consumption data may describe the consumption of the applicable resource (e.g., electrical energy, water, gas) being measured along with associated timestamps. Using the radio, the adaptive meter 110 may output the raw consumption data as streaming data.

Additionally or alternatively to the above, in some implementations, the MCU of the adaptive meter 110 performs some other minimal processing to the raw sensed data to produce the raw consumption data. For instance, the MCU may aggregate the raw sensed data based on short intervals to form the raw consumptions data. For instance, each interval may be thirty seconds, one minute, two minutes, or less than two minutes. The MCU may average, or otherwise aggregate, the raw sensed data for each such interval and may use the resulting average value, or other aggregate value, as raw consumption data for the corresponding interval. In that case, the adaptive meter 110 may output as the raw consumption data a stream of values, with each value representing an aggregated (e.g., average) resource consumption for a corresponding time interval. However, in some implementations, the meter 110 does not perform aggregation on the raw sensed data, and thus, the raw consumption data has not already been aggregated.

In some implementations, the adaptive meter 110 may output other data, such as other raw data, in addition to the raw consumption data. For instance, such other raw data may include information detected about the adaptive meter's neighbors (e.g., other adaptive meters 110 or other devices with which the adaptive meter 110 can communicate) in the smart grid 100. More generally, the adaptive meter 110 may detect information related to itself and may publish that information for processing by the fog processing system 150 or the cloud processing system 140, or both. The adaptive meter 110 may provide no processing or limited processing on such data prior to publishing that data, so as not to require as much computing resources as needed in a conventional meter.

To facilitate the above in some implementations, the adaptive meter 110 may be connected to two or more networks. For instance, through a resource distribution network, the adaptive meter 110 communicates with its neighbors (e.g., other meters 110 or gateways 120) in the smart grid 100, and through another communication network, the adaptive meter 110 communicates with the remote processing system 130. In some implementations, the adaptive meter 110 may use a single radio for each such network. Alternatively, however, the adaptive meter 110 may communicate over the resource distribution network using a first radio and over the other communication network using a second radio. Various implementations are possible and are within the scope of this disclosure.

Due to the meter 110 determining raw data and performing minimal, if any, processing on that raw data other than A/D conversion, some implementations of the adaptive meter 110 may support reduced capability and may have reduced computing resources as compared to a conventional meter. For example, the adaptive meter 110 need not include a display or a display driver; the adaptive meter 110 need not include an optical port or a driver for such a port. For another example, the adaptive meter 110 may have a smaller memory device as compared to a conventional meter, as less storage may be needed to stream raw data without having to temporarily store that raw data during processing. Rather, in some implementations, the adaptive meter 110 is essentially an IoT sensor with limited computational capability. For instance, an example of the adaptive meter 110 includes a sensor and a system-on-chip (SoC) component that performs the A/D conversion or other digital signal processing and transmits the result.

Some implementations described herein reduce (e.g., minimize) the cost of an endpoint (e.g., an adaptive meter 110) while maintaining a connected wireless IoT metrology sensor capability in that endpoint. For instance, an example of an adaptive meter 110 described herein has a cost of half or a third of the cost of a traditional utility meter. To this end, some or all data processing, management, decision-making, analytics, or other services may be decoupled from, and thus shifted from, the adaptive meter 110. This can reduce the computing resources needed at the adaptive meter 110. Further, the use of the fog 150 or the cloud 140 enables the adaptive meter 110 to be associated with value-added services that utilize data generated by the adaptive meter 110. Often, a utility service provider owns thousands or millions of endpoints; some implementations described herein can therefore significantly reduce the equipment cost to the utility service provider by reducing the computing resources needed for each endpoint while potentially maintaining or even adding available services that utilize data from those endpoints.

Within the smart grid 100, the adaptive meter 110 may be in communication with one or more neighbors, such as other meters or a gateway 120, to enable peer-to-peer monitoring or to provide an ad hoc network of communications within the smart grid 100. In some implementations, the gateway 120 routes communications to and from the adaptive meter 110 in the smart grid 100. For instance, the adaptive meter 110 may transmit raw consumption data or other data to the remote processing system 130 by routing the raw consumption data through the gateway 120, and the adaptive meter 110 may receive instructions or other data from the remote processing system 130 through the gateway 120. Thus, in some implementations, the gateway 120 may facilitate communications for the adaptive meter 110 within the smart grid 100, including those between the adaptive meter 110 and the remote processing system 130. It will therefore be understood that references in this disclosure to the adaptive meter 110 transmitting or receiving data may, but need not, involve routing through the gateway 120.

In some implementations, the adaptive meter 110 publishes its raw consumption data or other data (e.g., other raw data) or, in other words, makes the raw consumption data or other data available to one or more nodes in the remote processing system 130. Publishing the raw consumption data can be performed by one or more of various techniques. In one example, the adaptive meter 110 may transmit the raw consumption data to the remote processing system 130, such as to the cloud processing system 140 (e.g., to one or more cloud nodes 145), to the fog processing system 150 (e.g., to one or more fog nodes 155), or to both. In another example, the adaptive meter 110 transmits the raw consumption data to the fog processing system 150, and the fog processing system 150 transmits the raw consumption data to the cloud processing system 140, such that the adaptive meter 110 indirectly transmits the raw consumption data to the cloud processing system 140. In yet another example, the adaptive meter 110 transmits its raw consumption data to a storage device, such as a network-attached storage device or some other device that includes storage, which is accessible to the fog processing system 150 or the cloud processing system 140. Various implementations are possible and are within the scope of this disclosure.

In some implementations, data is shared throughout the smart grid 100 by way of a message bus 160. Generally, a message bus is a messaging infrastructure that enables various devices to use a shared interface. For instance, to implement the message bus 160 used in some implementations, the nodes in the remote processing system 130 may utilize a common data model, such as by operating internally in that common data model or by converting data to that common data model prior to transmission to another device. Additionally, in some implementations, either or both of the adaptive meter 110 and the gateway utilize this common data model, such as by operating internally in the common data model or by converting data to that common data model prior to transmission to another device. For instance, the gateway 120 converts data from the adaptive meter 110 into data appropriate for transmission through the message bus 160 prior to routing that data on behalf of the adaptive mere 110, and if needed, the gateway 120 converts data received via the message bus 160 from the remote processing system 130 into a format that is understandable by the adaptive meter 110, prior to forwarding that resulting converted data to the adaptive meter 110. Thus, the adaptive meter 110 (e.g., by way of the gateway 120) may use the message bus 160 to publish data, such as raw consumption data, and the fog processing system 150 and the cloud processing system 140 may use the message bus 160 to receive that data, to pass data between nodes, or to transmit data back to the adaptive meter 110. Various other uses of the message bus 160 are possible and are within the scope of this disclosure. In some implementations, communications among devices in the smart grid 100, via the message bus 160 or otherwise, may use one or more of various communication techniques or standards, such as 4G, 5G, ZigBee, Wireless Fidelity (WiFi), or Wireless Smart Utility Network (Wi-SUN).

As mentioned above, the remote processing system 130 may include a cloud processing system 140 and a fog processing system 150. The cloud processing system 140 may provide centralized processing 140 for various adaptive meters 110. The cloud processing system 140 may include one or more computing devices (i.e., nodes), referred to herein as cloud devices or cloud nodes 145, configured to perform processing to provide cloud-based services. The cloud processing system 140 may be configured to make decisions for adaptive meters 110 in the smart grid 100. In contrast, the fog processing system 150 may provide processing in a decentralized manner, potentially closer to the adaptive meter 110 in terms of connectivity or geography. As a result, the fog processing system 150 may be suitable for decision-making in real time or near-real time. The fog processing system 150 may include one or more computing devices (i.e., nodes), also referred to herein as fog devices or fog nodes 155, which perform processing to provide fog-based services. The fog processing system 150 may perform processing for, or related to, adaptive meters 110 within a geographic region associated with the fog processing system 150 and, thus, located proximate to the fog nodes 155. In some implementations, the smart grid 100 includes multiple fog processing systems 150, including a respective fog processing system 150 for each geographic region on the smart grid 100. In that case, each fog processing system 150 processes data (e.g., raw consumption data) associated with adaptive meters 110 that are nearby or, more specifically, that are within the geographic region associated with the fog processing system 150. A fog processing system 150 may be configured to make decisions for adaptive meters 110 associated with that fog processing system 150 (i.e., within the geographic region associated with the fog processing system 150).

Some implementations described herein reduce the cost of a meter 110 by removing processing capabilities from a network edge (i.e., from the meters 110) and placing such processing capabilities in a remote processing system 130 that is located outside the meter 110 itself. The use of a fog processing system 150 in some implementations enables the smart grid 100 to perform processing in real time or near-real time, due to the proximity of the fog processing system 150 to the meters 110 for which the fog processing system 150 performs processing. Further, the use of multiple fog processing systems 150 decentralizes certain processing in a manner that achieves effective load balancing. Additionally or alternatively, the use of a cloud processing system 140 enables centralized processing for tasks that are less time sensitive or for which centralized processing is desired for some other reason, such as for cost reduction due to consolidation or for data aggregation across meters 110 in various geographic regions.

The remote processing system 130 may perform various tasks based on data provided by the associated adaptive meters 110. Each of such tasks may take as input raw data, such as the raw consumption data, or may take as input data resulting from other processing performed (e.g., on the raw data) within the remote processing system 130. Various techniques may be used to process data in the remote processing system 130. For instance, such techniques can include machine learning techniques or others, and the techniques used can change over time. Examples of such tasks performed by the remote processing system 130 include load profiling, time-of-use (TOU) analysis, load disaggregation, grid health monitoring, grid topology and mapping, and grid analytics. In an example implementation, the fog processing system 150 performs processing tasks related to load profiling and grid health monitoring, as these tasks are time critical, and the cloud processing system 140 performs processing tasks related to TOU analysis, load disaggregation, grid topology and mapping, and grid analytics, as these tasks are less time critical.

As performed by the remote processing system 130, load profiling may include determining load profile data that describes the electrical profile of a load (i.e., a customer premises) being monitored by an adaptive meter 110. For instance, the remote processing system 130 may perform load profiling on the raw consumption data by aggregating (e.g., averaging) the raw consumption data according to intervals to form the load profile data. Thus, in the load profile data, values represent electrical energy consumption that occurred in corresponding time intervals. If the raw consumption data was already aggregated into short time intervals at the adaptive meter 110, then the load profile data may include values that are further aggregated based on longer time intervals. For instance, the time intervals represented in the load profile data may have a length of five minutes, fifteen minutes, thirty minutes, a day, thirty days, or a month.

Load profile data can provide detailed insight on how energy is consumed and how power flows through the smart grid 100. Load profile data can improve the understanding of the smart grid 100 and enhance its efficiency and robustness, such as by enabling the identification of bottlenecks and the estimation of the amount of renewable generation that can be safely accommodated. In some implementations, the fog processing system 150 or the cloud processing system 140, or both, can utilize the load profile data, such as by applying one or more machine learning models, to identify bottlenecks, estimate the amount of renewable energy that can be generated, determine pricing models, remediate any issues, or perform other tasks. A better understanding of the smart grid 100, as can be provided by the load profile data, can be translated into a more targeted and effective investment in grid upgrades.

In some implementations, the remote processing system 130 can perform load profiling on a per-meter basis or at a higher level across multiple meters 110. For instance, the fog processing system 150 may perform load profiling for each meter and may aggregate raw consumption data across multiple meters 110 in the geographic region associated with the fog processing system 150 to perform load profiling on the multiple meters 110 as a set. Analogously, the cloud processing system 140 may perform load profiling across multiple meters 110 across geographic regions of the smart grid 100. Specifically, for instance, load profile data can be determined through aggregation across all meters 110 connected to a transformer to better understand the load on that transformer, or load profile data can be determined through aggregation across all meters 110 connected to transformers that are connected to a substation to better understand the load on that substation. In some implementations, the determination of such load profile data across multiple meters 110 can be performed more efficiently by the remote processing system 130, rather than at individual meters as might be the case conventionally. Further, it may be more economical to place the computing power for generating such load profile data in the remote processing system 130 rather than in each individual meter or in a collection of individual meters.

As performed by the remote processing system 130, TOU analysis may include making determinations about when electrical energy consumption occurs. For instance, as part of the TOU analysis, the remote processing system 130 may compute macro-indicators such as total annual electricity consumption, peak consumption, average peak consumption, and distribution of peak hours of electricity consumption. In some implementations, TOU analysis takes as input raw consumption data or load profile data, either or both of which can be provided in clock-aligned intervals as determined by an adaptive meter 110 or by load profiling, whether at the meter 110 or elsewhere (e.g., in the fog processing system 150). In the former case, the one or more nodes performing the TOU analysis can receive the raw consumption data either directly or indirectly from the adaptive meter 110. In the latter case, the one or more nodes performing the TOU analysis can receive the load profile data from one or more fog nodes 155 or cloud nodes 145 that performed load profiling on the raw consumption data.

The output of the TOU analysis, also referred to as TOU data, can be used in various ways inside the remote processing system 130, outside the remote processing system 130, or both. For instance, TOU data may be used by a headend system or other system for billing purposes. In one example, if the TOU data indicates that peak demand is in the morning and the evening, TOU tariffs may be formed over those timeslots to enable establishing different rates so as to curb consumption during those timeslots. As a result of TOU tariffs, a utility service provider can optimize generation through reduced peaks and optimize consumption, thereby reducing the costs to consumers.

As performed by the remote processing system 130, load disaggregation involves determining which appliances (i.e., which specific loads) are in use on a customer premises. For instance, the fog processing system 150 or the cloud processing system 140 may apply machine learning or another technique to identify specific consumption signatures in the raw consumption data, where each such consumption signature corresponds to a particular appliance in use by the customer premises (i.e., on the customer premises).

The fog processing system 150, the cloud processing system 140, or both may perform grid health monitoring, grid topology and mapping, and other grid analytics. More specifically, in some implementations, the fog processing system 150 may perform grid health monitoring and grid topology and mapping, which may be time critical, and the cloud processing system 140 may perform other grid analytics that are less time critical. The fog processing system 150, or other aspect of the remote processing system 130, may monitor grid health and may determine grid topology and mapping (i.e., determining a map of connectivity of devices in the smart grid 100) based on raw data or other data provided by the adaptive meters 110 about their connections with other devices in the smart grid 100. This information may be used to provide efficient communications within the smart grid 100 and to remediate connectivity issues as needed. The cloud processing system, or other aspect of the remote processing system 130, may perform other grid analytics that are less time critical, such as those that are not likely to require remediation.

Through the performance of grid analytics, the fog processing system 150 or the cloud processing system 140 can provide one or more of various remediation techniques. For instance, the fog processing system 150 may receive data from multiple meters 110 that have been associated, such as through the grid topology and mapping, with a common transformer, and the fog processing system 150 may thus monitor the load on that transformer to ensure that the load is within the specifications of the transformer. If the load is not within the specification, the fog processing system 150 may issue an alert (e.g., to the utility service provider) so as to manage the potential aging or explosion of the transformer. In some implementations, the fog processing system 150 implements intelligent management of the transformer such that the fog processing system 150 can disconnect one or more homes from the transformer if the capacity of the transformer is compromised. For another example, grid analytics can be used to detect power theft or to detect devices with the potential for malevolent or damaging use, such as a photovoltaic inverter (PV) or other consumer-owned equipment that can be used to create the appearance of power flowing toward the power grid. For yet another example, electric vehicle charging can put significant strain on a utility grid once widely adopted. However, with grid analytics, the fog processing system 150 or the cloud processing system 140 can identify sources of this strain and can issue a message, during a peak period, to consumers to request a reduction of charging during that peak period. Various other practical applications are possible and are within the scope of this disclosure.

Additionally or alternatively to the above, the remote processing system 130 may perform other processing tasks, such as the following for example: safety and power quality, volt/VAR (voltage-ampere reactive) control, sub-second polling related to quality of service (QoS), distributed energy resources (DER) management, and phase identification. For instance, in an example implementation, the fog processing system 150 performs processing tasks related to safety and power quality, volt/VAR control, and sub-second polling related to QoS because these are time-critical tasks. For instance, the volt/VAR analysis could reveal a PV inverter that is out of phase and thus causing problems such as, for example, damage to connected equipment, load imbalances or instability in the power grid, or even power outages in the power grid. As a result of discovering such a PV inverter, the one or more nodes in the fog processing system 150, or additionally or alternatively the cloud processing system 140, may issue a message to the applicable consumer to request remediation, which can include requesting shutoff of the PV inverter. In some implementations, the cloud processing system 140 performs processing tasks related to DER management and phase identification, which are less time critical. Other processing tasks may additionally or alternatively be performed by the remote processing system 130.

Through the shifting of work from the adaptive meters 110 or from a headend system to the remote processing system 130, some implementations described herein provide various benefits over existing smart grids 100. Those benefits can be in terms of flexibility, scalability, adaptability, or revenue. In terms of flexibility, because of the decoupling of services from the endpoints, the endpoints can include a variety a hardware, software, or firmware, and service implementation need not be tied to any endpoint vendor in particular. In some implementations, the endpoints in the smart grid 100 need not have been manufactured by the same entity and may vary in their hardware, software, or firmware. Further, the services provided in the fog 150 or the cloud 140 need not be dependent on the specific endpoints used, and the hardware, software, or firmware used to provide such services in the fog 150 or the cloud 140 may vary over time or across services without impacting operation of the endpoints. This enables scalability of such services by, for instance, adding new nodes or modifying existing nodes without impacting the endpoints themselves. As described further below, the endpoints need not be modified to add, remove, or modify services, and thus an endpoint is highly adaptable in that the services associated with the endpoint can change without impact, or without significant impact, on the endpoint itself. Additionally or alternatively, the smart grid 100 supports subscription services. For instance, a service provider that provides services in the fog 150 or the cloud 140 can offer those services through a subscription model, thus enabling that service provider to bring in a recurring revenue similar to that used in Software as a Service (SaaS) services. Various other benefits are possible and are within the scope of this disclosure.

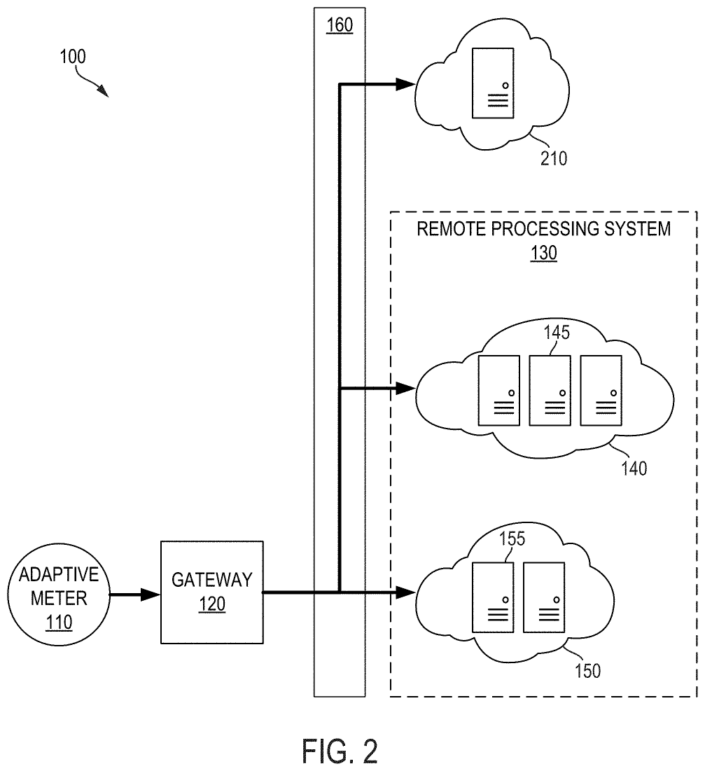

FIG. 2 is a diagram of another example of the smart grid 100, according to some implementations described herein. As shown in FIG. 2, the smart grid 100 may include a headend system 210, in addition to including one or more adaptive meters 110 and the remote processing system 130. The headend system 210 may perform centralized processing of data. The data processed by headend system 210 may include, for instance, raw consumption data, other raw data, or data resulting from the processing of raw consumption data by the remote processing system 130 (e.g., load profile data, TOU data). In some implementations, the headend system 210 is associated with, and managed by, a utility service provider associated with the smart grid 100.

In some implementations, the headend system 210 performs various centralized tasks, such as billing tasks, for some or all adaptive meters 110 in the smart grid 100. To enable the headend system 210 to perform such tasks, the headend system 210 may be configured to receive data from the adaptive meters 110 or from the remote processing system 130. In one example, for instance, adaptive meters 110 transmit their raw consumption data to the headend system 210, which can process the raw consumption data to perform billing or other centralized tasks. In another example, one or more fog nodes 155 or cloud nodes 145 transmit data to the headend system 210, where that data may be based on raw consumption data, and the headend system 210 further processes that data to perform billing or other centralized tasks.

As shown in FIG. 2, the headend system 210 may utilize the same message bus 160 used by other aspects of the smart grid system 100. As such, the headend system 210 is configured to communicate with the fog processing system 150, the cloud processing system 140, and the adaptive meter 110 as needed. The headend system 210 may be configured to communicate with the adaptive meters 110 or the remote processing system 130, over the message bus 160 or otherwise, using one or more of various communication techniques. Such communication techniques may include, for example, 4G, 5G, ZigBee, WiFi, or Wi-SUN.

In a typical existing smart grid, there is no remote processing system 130 for processing data related to utility meters, and the utility meters are managed in a fully centralized manner by a headend system. The headend system not only performs billing tasks but also pushes firmware updates, or is associated with an update server that pushes firmware updates, to the utility meters if a modification to the capabilities of the utility meters. As a result of this configuration, some or all services related to the utility meters have to communicate with the utility meters through the headend system. For instance, either the headend system manages such services or the headend system 210 passes communications between the utility meters and the applicable servers that manage such services.

In contrast, according to some implementations, the headend system 210 need not be responsible for all services related to the adaptive meters 110. As such, the utility service provider associated with the headend system 210 can focus on and specialize in specific services while leaving other services to other service providers (i.e., vendors). For instance, the headend system 210 can manage billing tasks, while other service providers can operate fog nodes 155 or cloud nodes 145 to provide various other services.

Further, while traditional headend systems play a role in pushing firmware to individual meters 110 when the services of those meters 110 requires modification, some implementations described herein enable updates by modifying the set of nodes in the remote processing system 130 instead. For instance, to add a service to a meter 110, one or more fog nodes 155 or cloud nodes 145 responsible for performing that service may be directed (e.g., by an applicable server associated with those nodes and operated by a service provider) to perform that service based on the raw data provided by the meter 110, or the meter 110 may be directed to provide its raw data to such one or more fog nodes 155 or cloud nodes 145. To modify a service provided to a meter 110, one or more fog nodes 155 or cloud nodes 145 responsible for performing that service may be updated with the applicable modification. Analogously, to remove a service from a meter 110, one or more fog nodes 155 or cloud nodes 145 responsible for performing that service may be directed (e.g., by an applicable server associated with those nodes and operated by a service provider) to no longer perform that service based on the raw data provided by the meter 110, or the meter 110 may be directed to stop providing its raw data to such one or more fog nodes 155 or cloud nodes 145. As such, services related to adaptive meters 110 can be modified easily and relatively inexpensively, without firmware updates to the adaptive meters 110 themselves. Similarly, testing of new services is also simplified in some implementations, as testing can require modification to fog nodes 155 or cloud nodes 145, rather than modification to an adaptive meter 110.

Although modification to services provided through the remote processing system 130 typically need not require a firmware update at the meters 110, it may occasionally be required for meters 110 to have their firmware updated. For instance, a firmware may be required to fix a bug or to update a driver for a radio of an adaptive meter 110. If a firmware update is needed at an adaptive meter 110 itself, the headend system 210 or another device can push a firmware update to the meter 110 as needed; however, due to the reduced capabilities of the meter 110, that firmware update is likely to be small as compared to a firmware update for a conventional meter. Thus, when needed, a firmware update may require reduced computing resources and reduced room for error.

It will be understood that FIG. 2, as well as other figures herein, illustrates a non-limiting example of the smart grid 100 and that a headend system 210 is not required to be included in the smart grid 100. In some implementations, for instance, tasks conventionally performed by a headend system 210 may be performed by nodes in the remote processing system 130, such as by one or more fog nodes 155 or cloud nodes 145. For example, the cloud processing system 140 can perform billing tasks, such as determining billing data, generating bills, or issuing bills, rather than such tasks being performed by a headend system 210. Thus, some implementations described herein shift tasks that are conventionally performed by a headend system 210 to the cloud processing system 140 or the fog processing system 150.

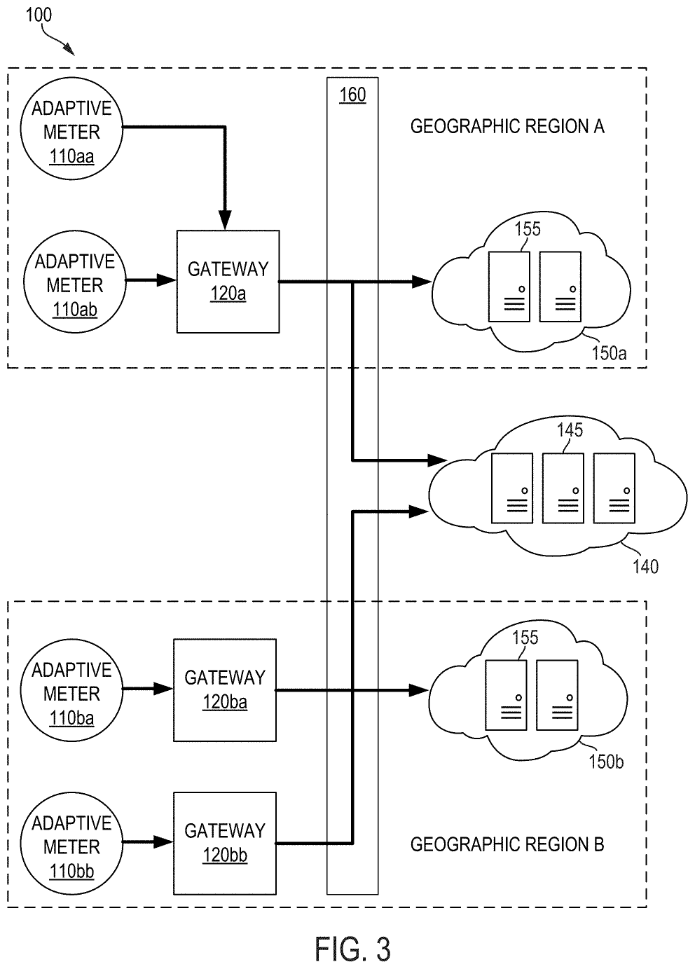

FIG. 3 is a diagram of yet another example of the smart grid 100, according to some implementations described herein. As shown in FIG. 3, multiple fog processing systems 150 may be included in the smart grid 100. Each fog processing system 150 may be associated with a set of meters 110, where those meters 110 are proximate to the fog processing system 150 in terms of geography or connectivity. As a result, the fog processing system 150 can process raw consumption data received from those meters 110 in real time or in near-real time. In this example, the cloud processing system 140 is configured to process raw consumption data from some or all of the adaptive meters 110, regardless of which fog processing systems 150 are associated with such adaptive meters 110. Although no headend systems 210 are shown in FIG. 3, one or more headend systems 210 may be included in the smart grid system 100 regardless of the number of fog processing systems 150 that are used.

The example of FIG. 3 illustrates two fog processing systems 150, but more or fewer fog processing systems 150 may be included in the smart grid 100. In this example, a first adaptive meter 110aa and a second adaptive meter 110ab are both located in Geographic Region A, which is made up of one or more geographic areas that are closely communicatively coupled to a first fog processing system 150a. As such, both of these adaptive meters 110 are assigned to the first fog processing system 150a. The first fog processing system 150a therefore processes the raw consumption data from the first adaptive meter 110aa and the second adaptive meter 110ab. The first fog processing system 150a can perform such processing in near-real time due to proximity and, thus, due to receiving the raw consumption data from those adaptive meters 110 in near-real time.

Also in this example, a third adaptive meter 110ba and a fourth adaptive meter 110bb are both located in Geographic Region B, which is made up of one or more geographic areas that are closely communicatively coupled to a second fog processing system 150b. As such, both of these adaptive meters 110 are assigned to the second fog processing system 150b. The second fog processing system 150b therefore processes the raw consumption data from the third adaptive meter 110ba and the fourth adaptive meter 110bb. The second fog processing system 150b can perform such processing in near-real time due to proximity and, thus, due to receiving the raw consumption data from those adaptive meters 110 in near-real time.

The geographic regions of different fog processing systems 150 may overlap, because a geographic region need not have strict boundaries. Rather, in this disclosure, a geographic region is defined by its associated fog processing system 150. A geographic region is an area or set of areas in which adaptive meters 110 are communicatively close enough to a particular fog processing system 150 to enable that fog processing system 150 to process raw consumption data from such adaptive meters 110 in real time or near-real time. More specifically, for example, an adaptive meter 110 in a geographic region associated with a fog processing system 150 may be communicatively closer to that fog processing system 150 than the adaptive meter 110 is to the cloud processing system 140; in other words, communications from the adaptive meter 110 reach the fog processing system 150 associated with that adaptive meter 110 faster than they reach the cloud processing system 140.

Adaptive meters 110 can be assigned to fog processing systems 150 using one or more of various techniques. In some implementations, an adaptive meter 110 is assigned to the closest fog processing system 150 in terms of connectivity, which may but need not be the geographically closest fog processing system 150. In one example, an adaptive meter 110 unilaterally chooses its fog processing system 150 (i.e., the fog processing system 150 to which the adaptive meter 110 sends its raw consumption data) based on which fog processing system 150 responds to the adaptive meter's registration request. For instance, the adaptive meter 110 may broadcast a registration request (e.g., via the message bus 160), and fog processing systems 150 that receive the broadcast may respond, thus confirming that such fog processing systems 150 are nearby and available. In some implementations, if multiple fog processing systems 150 respond, then the adaptive meter 110 may select for use the fog processing system 150 whose response is received first, since the order of receipt of such responses may indicate communicative proximity.

In some implementations, a manual or automated administrator, such as one running in the headend system 210, assigns the adaptive meter 110 to a fog processing system 150. In one example, the administrator assigns the adaptive meter 110 to a proximate fog processing system 150 when the adaptive meter 110 is installed, in which case the adaptive meter 110 may be programmed with information (e.g., an Internet Protocol (IP) address) for reaching the fog processing system 150 to which the adaptive meter 110 is assigned. In another example, the administrator assigns the adaptive meter 110 to a proximate fog processing system 150 when the adaptive meter 110 joins the smart grid 100 (e.g., when the adaptive meter 110 comes online and registers with the headend system 210 or the cloud processing system 140); in that case, the gateway 120 or other device in the smart grid 100 may provide the adaptive meter 110 with information needed to communicate with the assigned fog processing system 150. Additionally or alternatively, the administrator assigns the adaptive meter 110 to a fog processing system 150 in a manner that achieves load balancing across the various fog processing systems 150. For instance, the administrator may enforce a maximum number of adaptive meters 110 per fog processing system 150, or the administrator may assign the adaptive meter 110 so as to maintain an approximately equal number of adaptive meters 110 per fog processing system 150.

In additional or alternative implementations, the assignment of where intelligence is processed (i.e., the assignment of an adaptive meter 110 to an appropriate fog processing system 150 that processes data from the adaptive meter 110) is determined based on the communication technology between the adaptive meter 110 and the fog processing system 150. If the communication technology used is RF mesh, for instance, then rules applicable to the forming of a stable RF mesh are applied to match the adaptive meter 110 with a fog processing system 150. For instance, some aspect of the smart grid 100, such as the gateway 120 for the adaptive meter 110, assigns the adaptive meter 110 to a fog processing system 150 such that a high Received Signal Strength Indicator (RSSI) signal strength is achieved between the adaptive meter 110 and its associated fog processing system 150, coupled with a low latency between the adaptive meter 110 and the fog processing system 150. However, various implementations for assigning an adaptive meter 110 to an appropriate fog processing system 150 are possible and are within the scope of this disclosure.

As also illustrated in FIG. 3, various configurations of gateways 120 and adaptive meters 110 are possible. For instance, as shown with respect to the third adaptive meter 110ba and the fourth adaptive meter 110bb, adaptive meters 110 assigned to a common fog processing system 150 need not have a common gateway. As shown with respect to the first adaptive meter 110aa and the second adaptive meter 110ab, however, adaptive meters 110 may have a common gateway 120. In addition to acting as a router of communications, a gateway 120 may also behave as a collector. More specifically, a gateway 120 may collect raw consumption data from various connected adaptive meters 110 and may provide that raw consumption data to other devices, such as to the headend system 210, the fog processing system 150, or the cloud processing system 140. Various configurations of gateways 120 are possible and are within the scope of this disclosure.

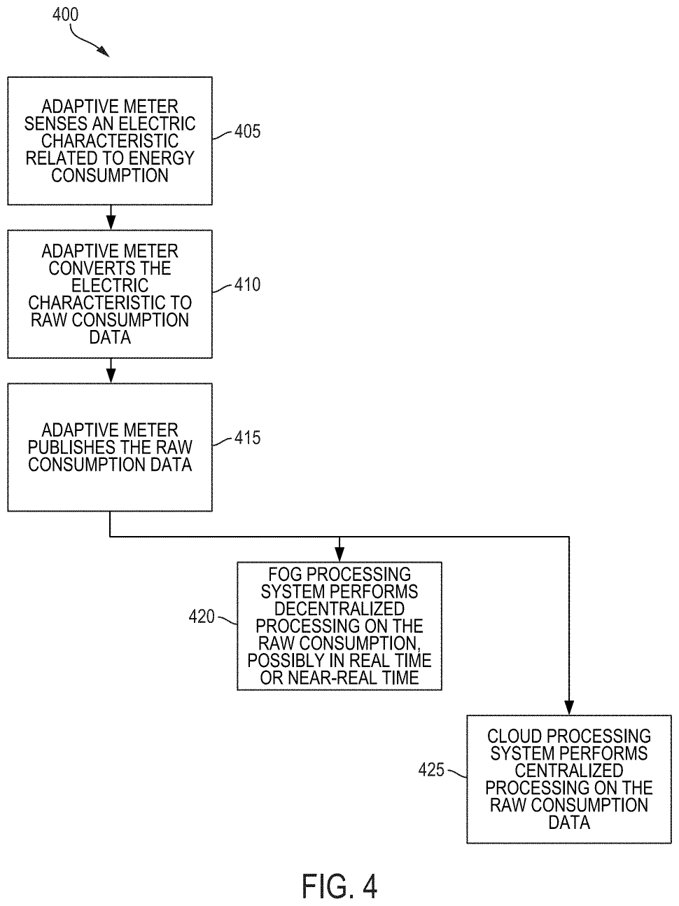

FIG. 4 is a flow diagram of a method 400 of processing data through the smart grid 100, according to some implementations described herein. This method 400 is provided for illustrative purposes only and does not limit the various possible implementations of the smart grid 100 or its capabilities.

As shown in FIG. 4, at block 405, an adaptive meter 110 senses an electrical characteristic related to energy consumption. For instance, the adaptive meter 110 may utilize its sensor to sense voltage or current between the power grid and the load (i.e., the customer premises). In some implementations, this sensing may occur on a continuous basis.

In the example of this method 400, the adaptive meter 110 is an electric meter and therefore senses an electrical characteristic. However, alternatively, the adaptive meter 110 could be some other type of meter, and in that case the characteristic sensed would be related to the resource whose consumption is being measured by the adaptive meter 110. For instance, if the adaptive meter 110 is a water meter, then the characteristic sensed is indicative of water consumption, or if the adaptive meter 110 is a gas meter, then the characteristic sensed is indicative of gas consumption. Various implementations are possible and are within the scope of this disclosure.

At block 410, the adaptive meter 110 converts the electrical characteristic to raw consumption data. For instance, as discussed above, the adaptive meter 110 may include a converter configured to convert analog, such as the detection of voltage or current, to digital, such as a numerical representation of the voltage or current. Thus, converting the electrical characteristic to the raw consumption data may involve, at least, converting the electrical characteristic to digital data. The raw consumption data may be a digital representation of the electrical characteristic that is being sensed. For instance, the consumption data may be a stream of numerical values, each numerical value representing a measurement of the electrical characteristic at a corresponding time. For example, the numerical values may be values representing the electrical characteristic (e.g., the voltage or the current) and may correspond to times that are sub-seconds or seconds apart.

At block 415, the adaptive meter 110 publishes the raw consumption data. For instance, to publish the consumption data, the adaptive meter 110 may transmit the raw consumption data to one or more fog nodes 155 or cloud nodes 145 in the remote processing system 130. Additionally or alternatively, the adaptive meter 110 may transmit the raw consumption data to a headend system 210 if a headend system 210 is included in the smart grid 100. Additionally or alternatively, the adaptive meter 110 may publish other raw data as well, such as data describing connectivity with other meters, gateways 120, or other devices within the smart grid 100.

The adaptive meter 110 may make the raw consumption data available to the remote processing system 130 or the headend system 210 in various ways. In some example implementations, for instance, the adaptive meter 110 transmits the raw consumption data to the fog processing system 150, which performs further processing on the raw consumption data and then transmits the resulting processed consumption data, as well as optionally the raw consumption data, to the cloud processing system 140 or the headend system 210, or both. In some other example implementations, the adaptive meter 110 transmits the raw consumption data to both the fog processing system 150 and the cloud processing system 140, which both perform processing on the raw consumption data and which exchange resulting processed consumption data with each other as needed; in such example implementations, the fog processing system 150 or the cloud processing system 140, or both, may transmit processed consumption data to the headend system 210 as needed. Various implementations are possible and are within the scope of this disclosure.

In some implementations, block 405, 410, and 415 are ongoing and thus occur in parallel. In other words, during normal operation of the adaptive meter 110, the sensor continuously senses the electrical characteristic, the converter continuously converts the electrical characteristic to digital data to produce the raw consumption data, and the radio continuously outputs that consumption data as streaming data.

At block 420, the fog processing system 150 accesses the raw consumption data from the adaptive meter 110 and performs decentralized processing on that raw consumption data, as well as on the raw consumption data from other adaptive meters 110 associated with the fog processing system 150. As described above, the fog processing system 150 may provide decentralized processing close to the edge (i.e., close to the meters 110 themselves), which can enable insights to be generated in real time or near-real time. For example, in some implementations, the fog processing system 150 may perform processing to execute one or more of the following tasks based on the raw consumption data: load profiling, grid health monitoring, safety and power quality analysis, volt/VAR control, or sub-second polling for QoS. Further, in some implementations, the fog processing system 150 receives raw consumption data related to a first set of adaptive meters 110, such as adaptive meters 110 within a geographic region. As such, the fog processing system 150 may be configured to determine aggregated data across the first set of meters 110 or to otherwise perform processing to determine insights about the first set of meters 110.

At block 425, the cloud processing system 140 accesses the raw consumption data from the adaptive meter 110 and performs centralized processing on that raw consumption data, as well as on the raw consumption data from other adaptive meters 110 associated with the cloud processing system 140 (e.g., some or all other adaptive meters 110 in the smart grid 100). As described above, the cloud processing system 140 may provide centralized processing for tasks that are not time critical, such that the computing resources needed for the centralized processing need not be duplicated across multiple meters 110 or multiple fog processing systems 150. For example, in some implementations, the cloud processing system 140 may perform processing to execute one or more of the following tasks based on the raw consumption data: TOU analysis, load disaggregation, grid topology and mapping, grid analytics, DER management, or phase identification. Further, in some implementations, the cloud processing system 140 receives raw consumption data related to a total set of adaptive meters 110, such as all adaptive meters 110 in the smart grid 100 or all adaptive meters 110 associated with services executed in the cloud processing system 140. As such, the cloud processing system 140 may be configured to determine aggregated data across the total meters 110 or to otherwise perform processing to determine insights about the total set of meters 110.

In some implementations, block 420 and block 425 are ongoing and thus occur in parallel with each other as well as in parallel with blocks 405, 410, and 415. For instance, the fog processing system 150 may process the raw consumption data from the adaptive meter 110, other raw data from the adaptive meter 110, or other data (e.g., data resulting from having processed the raw consumption data) while the cloud processing system 140 is also processing the raw consumption data from the adaptive meter 110, other raw data from the adaptive meter 110, or other data.

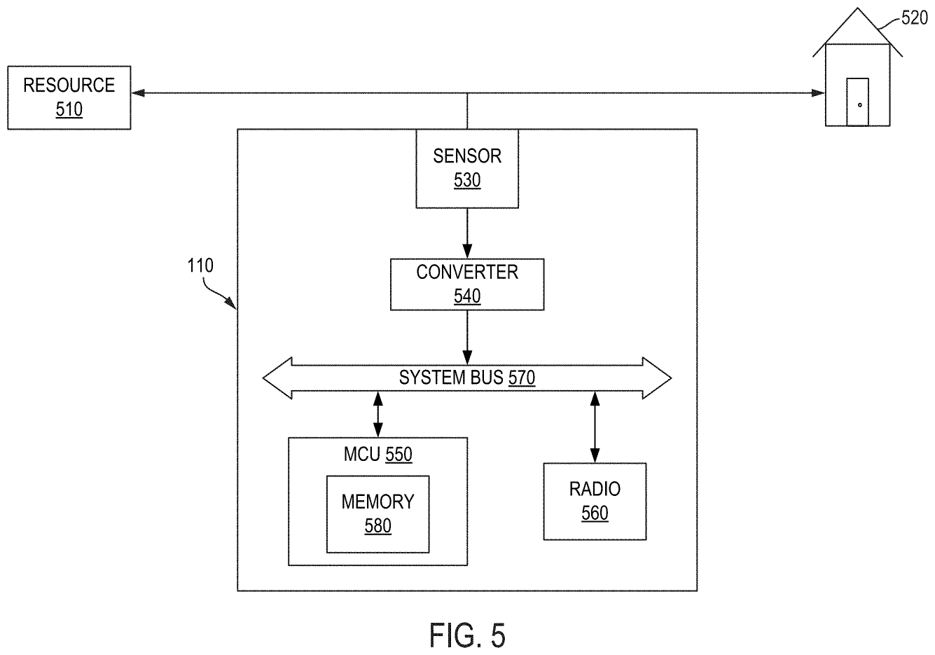

FIG. 5 is a diagram of an adaptive meter 110 in the smart grid, according to some implementations described herein. For example, and not by way of limitation, the adaptive meter 110 may be an electric meter, a water meter, a gas meter, or another type of meter that measures consumption of a resource 510 on a premises 520. As discussed above, the adaptive meter 110 may include a sensor 530, a converter 540, an MCU 550 or other processing unit, and a radio 560. A system bus 570 may connect together the converter 540, the MCU 550, and the radio 560 to enable these components to communicate with one another as needed for operation of the adaptive meter 110.

In some implementations, the sensor 530 detects a signal (i.e., an electrical characteristic) indicating use of the resource 510, and the converter 540 converts that signal to digital data for input into the MCU 550. The MCU 550 may direct the radio 560 to transmit raw consumption data, which may be based on the digital data. In some implementations, the raw consumption data is the same as the digital data received by the MCU 550 or is minimally processed. For instance, the MCU 550 may aggregate the digital data into short intervals, or the MCU 550 may simply transform the digital data into an appropriate format for transmission (e.g., as needed for the message bus 160). The radio 560 may be configured to utilize 4G, 5G, ZigBee, WiFi, Wi-SUN, or another communication technique and may thus transmit the raw consumption data using one or more of such communication techniques.

In some implementations, the adaptive meter 110 may also include a memory 580, which may be volatile memory (e.g., random-access memory (RAM)), nonvolatile memory (e.g., flash storage), or both. As shown in FIG. 5, the memory 580 may be integrated with the MCU 550. The MCU 550 may store the digital data or the raw consumption data on the memory 580 as needed to generate the raw consumption data and to enable transmitting the raw consumption data by the radio 560. There may be a regulatory or customer requirement for the adaptive meter 110 store the raw consumption data locally for a period of time, and in that case, the memory 580 may be used to store the raw consumption data for at least the time required. In additional or alternative implementations, the memory 570 may be separate from the MCU 550 rather than being integrated with the MCU as shown in FIG. 5.

More generally, an adaptive meter 110 may include components configured for basic metering and communicative processes, but the adaptive meter 110 may lack certain other components typically incorporated into a conventional utility meter. For instance, the adaptive meter 110 may lack one or more of the following: an integrated display and a driver for that display, a local optical port, or a local demand reset switch. Additionally or alternatively, compared to a traditional utility meter, the adaptive meter 110 may include a decreased amount of storage (e.g., a smaller memory 580), a slower MCU 550, or otherwise less powerful or less efficient computational resources. Various implementations are possible and are within the scope of this disclosure.

Numerous specific details are set forth herein to provide a thorough understanding of the claimed subject matter. However, those skilled in the art will understand that the claimed subject matter may be practiced without these specific details. In other instances, methods, apparatuses, or systems that would be known by one of ordinary skill have not been described in detail so as not to obscure claimed subject matter.

The features discussed herein are not limited to any particular hardware architecture or configuration. A computing device can include any suitable arrangement of components that provide a result conditioned on one or more inputs. Suitable computing devices include multipurpose microprocessor-based computer systems accessing stored software (i.e., computer-readable instructions stored on a memory of the computer system) that programs or configures the computing system from a general-purpose computing apparatus to a specialized computing apparatus implementing one or more aspects of the present subject matter. Any suitable programming, scripting, or other type of language or combinations of languages may be used to implement the teachings contained herein in software to be used in programming or configuring a computing device.

Aspects of the methods disclosed herein may be performed in the operation of such computing devices. The order of the blocks presented in the examples above can be varied; for example, blocks can be re-ordered, combined, and/or broken into sub-blocks. Certain blocks or processes can be performed in parallel.

The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included herein are for ease of explanation only and are not meant to be limiting.

While the present subject matter has been described in detail with respect to specific aspects thereof, it will be appreciated that those skilled in the art, upon attaining an understanding of the foregoing, may readily produce alterations to, variations of, and equivalents to such aspects. Accordingly, it should be understood that the present disclosure has been presented for purposes of example rather than limitation and does not preclude inclusion of such modifications, variations, and/or additions to the present subject matter as would be readily apparent to one of ordinary skill in the art.

What is claimed is:

1. A utility meter connected to a power grid and to a customer premises, the utility meter comprising:
a sensor configured to detect an electrical characteristic of electricity usage of the power grid by the customer premises;
an analog-to-digital (A/D) converter configured to convert the electrical characteristic to raw consumption data describing the electricity usage by the customer premises; and
a radio configured to transmit the raw consumption data output by the A/D converter to a remote processing system, wherein the remote processing system comprises:
a fog processing system comprising one or more fog devices associated with a geographic region of the utility meter, the fog processing system configured to perform data processing on the raw consumption data and on regional raw consumption data received from a first set of endpoints inside the geographic region, wherein the first set of endpoints comprises the utility meter.

2. The utility meter of claim 1, wherein the remote processing system further comprises a cloud processing system comprising one or more cloud devices, the cloud processing system configured to perform centralized data processing on the raw consumption data and on various raw consumption data from the first set of endpoints inside the geographic region and from other endpoints outside the geographic region.

3. The utility meter of claim 1, wherein the radio transmits the raw consumption data as a data stream comprising a series of numerical values, each numerical value in the series representing a respective value of the electrical characteristic at a corresponding time.

4. The utility meter of claim 3, wherein the radio transmits the raw consumption data as a real-time data stream.

5. The utility meter of claim 1, wherein the utility meter is associated with one or more subscription services provided by the remote processing system.

6. A system comprising:
a utility meter connected to a resource and to a customer premises, the utility meter comprising:
a sensor configured to detect a characteristic of usage of the resource by the customer premises;
a converter configured to convert the characteristic to raw consumption data describing the usage by the customer premises; and
a radio configured to transmit the raw consumption data;
a remote processing system configured to receive the raw consumption data from the utility meter, the remote processing system comprising:
a fog processing system comprising one or more fog devices associated with a geographic region of the utility meter, the fog processing system configured to perform data processing on the raw consumption data and on regional raw consumption data received from a first set of endpoints inside the geographic region, wherein the first set of endpoints comprises the utility meter; and
a cloud processing system comprising one or more cloud devices, the cloud processing system configured to perform centralized data processing on the raw consumption data and on various raw consumption data from the first set of endpoints inside the geographic region and from other endpoints outside the geographic region.

7. The system of claim 6, wherein the converter is an analog-to-digital (A/D) converter, and wherein the raw consumption data transmitted by the radio is a real-time data stream of numerical values output by the A/D converter.

8. The system of claim 7, wherein the fog processing system performs real-time processing on the raw consumption data.

9. The system of claim 6, further comprising:
a second utility meter;
wherein the remote processing system further comprises a second fog processing system associated with a second geographic region of the second utility meter, the second fog processing system configured to perform data processing on second raw consumption data received from the second utility meter and on second regional consumption data received from a second set of endpoints inside a second geographic region, wherein the second set of endpoints comprises the second utility meter.

10. The system of claim 9, wherein the fog processing system is configured to make decisions for the first set of endpoints in the geographic region, and wherein the second fog processing system is configured to make decisions for the second set of endpoints in the second geographic region.

11. The system of claim 6, wherein the fog processing system is configured to compute intervals of load profile data based on the raw consumption data.

12. The system of claim 11, wherein the fog processing system is configured to compute time of use data based on the intervals of load profile data.

13. The system of claim 11, wherein the fog processing system is configured to perform load disaggregation to determine which appliances are in use by the customer premises, based on the raw consumption data.

14. The system of claim 6, wherein the utility meter, the fog processing system, and the cloud processing system are configured to communicate with one another via a common message bus.

15. The system of claim 6, wherein a server updates a feature associated with the utility meter by updating a service in the remote processing system.

16. The system of claim 6, wherein a server adds a feature to the utility meter by configuring a service in the remote processing system to process the consumption data from the utility meter.

17. The system of claim 16, wherein the server removes the feature from the utility meter by configuring the service in the remote processing system to stop processing the consumption data from the utility meter.

18. A method comprising:
connecting, by a utility meter, to a power grid;
connecting, by the utility meter, to a customer premises;
utilizing, by the utility meter, a sensor to determine an electrical characteristic indicating electricity usage of the power grid by the customer premises;
converting, by the utility meter, the electrical characteristic to raw consumption data describing the electricity usage by the customer premises;
transmitting, by the utility meter, the raw consumption data describing the electricity usage to a fog processing system for data processing of regional consumption data received from a first set of endpoints inside a geographic region associated with the fog processing system, the fog processing system comprising one or more fog devices;
transmitting, by the utility meter, the consumption data describing the electricity usage to a cloud processing system for centralized data processing of various consumption data received from the first set of endpoints inside the geographic region and a second set of endpoints outside the geographic region, the cloud processing system comprising one or more cloud devices.

19. The method of claim 18, wherein transmitting the raw consumption to the fog processing system comprises transmitting to the fog processing system a real-time data stream describing electricity usage at sub-second intervals.

20. The method of claim 18, further comprising:
receiving a request to add a new subscription feature to the utility meter; and
responsive to the request, configuring the utility meter to transmit the raw consumption data to a node in the fog processing system, the node in the fog processing system being associated with the new subscription feature.
